(19) United States
(12) Patent Application Publication
(10) Pub. No.: US 2025/0054922 A1
(43) Pub. Date: Feb. 13, 2025

(54) DISPLAY SCREEN HAVING LIGHT-EMITTING DIODES

(71) Applicant: Aledia, Echirolles (FR)

(72) Inventors: Ivan-Christophe Robin, Grenoble (FR); Philippe Gilet, Teche (FR); Tiphaine Dupont, Grenoble (FR)

(73) Assignee: Aledia, Echirolles (FR)

(21) Appl. No.: 18/719,768

(22) PCT Filed: Dec. 14, 2022
(86) PCT No.: PCT/EP2022/085820

§ 371 Date: Jun. 13, 2024

(30) Foreign Application Priority Data
Dec. 21, 2021 (FR) FR2114167

(51) Int. Cl. H01L 25/075; H01L 33/62

(52) U.S. Cl. CPC H01L 25/0753; H01L 33/62

(57) ABSTRACT

A display screen including a support including first and second opposite surfaces and holes on the first surface; photoluminescent blocks in at least part of the holes; a glue layer covering the first surface; display sub-pixels bonded to the support by the glue layer, each display sub-pixel including third and fourth opposite surfaces, the third surface being on the side of the support, and electrically-conductive pads exposed on the fourth surface; a filling layer covering the first surface between the display sub-pixels; and electrically-conductive tracks extending on the filling layer and on the fourth surfaces of the display sub-pixels in electrical and mechanical contact with the electrically-conductive pads.

The present patent application claims the priority benefit of French patent application FR21/14167 which is herein incorporated by reference.

### TECHNICAL BACKGROUND

The present disclosure generally concerns display screens comprising light-emitting diodes.

### PRIOR ART

A pixel of an image corresponds to the unit element of the image displayed by a display screen. For the display of color images, a display screen generally comprises, for the display of each pixel of the image, at least three components, also called display sub-pixels, which each emit a light radiation substantially in a single color (for example, red, green, and blue). The superposition of the radiations emitted by the three display sub-pixels provides the observer with the colored sensation corresponding to the pixel of the displayed image. In this case, the assembly formed by the three display sub-pixels used for the display of a pixel of an image is called display pixel of the display screen. Each display sub-pixel may comprise a light source, particularly a light-emitting diode.

The display pixels may be distributed in an array, each display pixel being located at the intersection of a row (or line) and of a column of the array. Generally, each row of display pixels is successively selected, and the display pixels of the selected row are programmed to display the desired image pixels.

According to the used light-emitting diode manufacturing technologies, it may be necessary, for certain display sub-pixels, to cover the light-emitting diodes of the display sub-pixel with a photoluminescent block comprising luminophores adapted, when they are excited by the light emitted by the associated light-emitting diodes, to emitting light at a wavelength different from the wavelength of the light emitted by the associated light-emitting diodes.

An active array is a screen drive architecture enabling to maintain all the pixel rows active for the entire duration of an image, conversely to arrays called passive, where each row is only active for a time T=Tframe/N (where Tframe is the duration of the image and N is the number of rows of the screen). This enables to increase the luminosity of the display screen. Further, it is possible to send low voltage or current levels over the array control lines, which enables to display more significant data flows.

A method of manufacturing a display screen with an active array comprises depositing the light-emitting diodes on a support, also called slab, containing the drive electronics of the display pixels, and forming the photoluminescent blocks on the light-emitting diodes of the concerned display sub-pixels. To improve the contrast of a display screen, a possibility further comprises forming a black-colored opaque layer on the slab which exhibits openings at the level of each display sub-pixel. A disadvantage is that such a manufacturing method may be complex.

### SUMMARY OF THE INVENTION

Another object of an embodiment is to provide a display screen comprising light-emitting diodes overcoming all or part of the disadvantages of existing display screens comprising light-emitting diodes.

An embodiment provides a display screen comprising:
a support comprising first and second opposite surfaces and holes on the first surface;
photoluminescent blocks in at least part of the holes;
a glue layer covering the first surface;
display sub-pixels bonded to the support by the glue layer, each display sub-pixel comprising third and fourth opposite surfaces, the third surface being on the side of the support, and conductive pads electrically exposed on the fourth surface;
a filling layer covering the first surface between the display sub-pixels; and
electrically-conductive tracks extending on the filling layer and on the fourth surfaces of the display sub-pixels in electrical and mechanical contact with the electrically-conductive pads.

Such a structure allows the direct transfer of the display sub-pixels onto the support comprising the photoluminescent blocks, conversely to a conventional method where the display pixels/display sub-pixels are deposited on a slab comprising the control electronics and the photoluminescent blocks are then formed on the display pixels/display sub-pixels. The manufacturing of the photoluminescent blocks is thus eased.

According to an embodiment, each display sub-pixel comprises light-emitting diodes closer to the third surface than to the fourth surface.

According to an embodiment, each display sub-pixel comprises a stack of a first electronic circuit comprising the light-emitting diodes and of a second electronic circuit comprising electronic components configured to control the light-emitting diodes. This enables, for each display sub-pixel, to integrate the control electronics of the light-emitting diodes of the display sub-pixel directly in the display sub-pixel. The number of transfers of components forming the display screen is thus limited. The second electronic circuits do not interfere with the radiations emitted by the light-emitting diodes and do not take up too much space on the surface of the support. There is further no need to form an electric link or connection between first and second electronic circuits after transfer onto the support.

According to an embodiment, the filling layer is reflective for the radiations emitted by the display sub-pixels and the photoluminescent blocks. This enables to improve, for each display sub-pixel, the guiding of the radiation emitted by the light-emitting diodes of the display sub-pixel towards the hole in front of it.

According to an embodiment, the display screen further comprises a first layer opaque to the radiations emitted by the display sub-pixels and the photoluminescent blocks opposite to the first surface and comprising openings in front of the third surface of each display sub-pixel. This enables to improve the contrast of the display screen.

According to an embodiment, the display screen comprises blocks of a material scattering the radiation emitted by the display sub-pixels in at least another part of the holes. This enables, for each display sub-pixel located in front of a block of the scattering material, to improve the homogeneity of the intensity of the radiation emitted by the display sub-pixel.

According to an embodiment, the support comprises a base transparent to the radiations emitted by the display sub-pixels and the photoluminescent blocks covered with a second layer containing the holes. This enables to facilitate the manufacturing of the support.

According to an embodiment, the second layer is reflective for the radiations emitted by the display sub-pixels and the photoluminescent blocks. This enables to improve the guiding of the radiation emitted by the light-emitting diodes of the display sub-pixel in the holes.

According to an embodiment, the display screen further comprises, between the base and the second layer, a third layer transparent to the radiations emitted by the display sub-pixels and the photoluminescent blocks and having a refraction index smaller than 2. The third layer may allow the bonding of the second layer to the base.

According to an embodiment, the display screen comprises a coating reflective for the radiations emitted by the display sub-pixels and the photoluminescent blocks, covering the lateral wall of each hole. This enables to improve the guiding of the radiation emitted by the light-emitting diodes of the display sub-pixel in the holes.

According to an embodiment, the display screen comprises a fourth layer, transparent to the radiations emitted by the display sub-pixels and the photoluminescent blocks and having a refraction index smaller than 1.5, covering the bottom of each hole. The fourth layer enables to increase the conversion efficiency of the photoluminescent blocks.

According to an embodiment, the display screen comprises, for the holes containing the photoluminescent blocks, a color filter layer interposed between the photoluminescent blocks and the bottoms of the holes. This enables to improve the emission spectrum of the radiation emitted by the emission surface.

According to an embodiment, the photoluminescent blocks contain quantum dots.

An embodiment also provides a method of manufacturing a display screen such as previously defined, comprising the following steps:
forming the holes on the first surface of the support;
forming of the photoluminescent blocks in at least part of the holes;
deposition of a glue layer covering the first surface;
arranging and bonding of the display sub-pixels bonded to the support by the glue layer, on the side of the third surfaces;
forming of the filling layer covering the first surface between the display sub-pixels; and
forming of the electrically-conductive tracks extending on the filling layer and on the fourth surfaces of the display sub-pixels.

Conversely to a conventional method where the display pixels/display sub-pixels are deposited on a slab comprising the control electronics and the photoluminescent blocks are then formed on the display pixels/display sub-pixels, the present method provides the direct transfer of the display pixels/display sub-pixels onto the support comprising the photoluminescent blocks. This enables to simplify the manufacturing of the display screen.

According to an embodiment, the method comprises the steps of:
forming of a wafer comprising a plurality of said display sub-pixels; and
cutting of the wafer to separate said display sub-pixels.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 partially and schematically shows an example of a display screen;

FIG. 2 is a partial simplified cross-section view of an embodiment of a display screen;

FIG. 3 is a partial simplified cross-section view of another embodiment of a display screen;

FIG. 4 is a partial simplified cross-section view of another embodiment of a display screen;

FIG. 5 is a partial simplified cross-section view of another embodiment of a display screen;

FIG. 6 is a partial simplified cross-section view of another embodiment of a display screen;

FIG. 7 is a partial simplified cross-section view of another embodiment of a display screen;

FIG. 8 is a partial simplified cross-section view of another embodiment of a display screen;

FIG. 9 is a partial simplified cross-section view of an embodiment of a display sub-pixel;

FIG. 10 illustrates a step of an embodiment of a method of manufacturing the display screen of FIG. 2;

FIG. 11 illustrates another step of the method;

FIG. 12 illustrates another step of the method;

FIG. 13 illustrates another step of the method;

FIG. 14 illustrates another step of the method;

FIG. 15 illustrates another step of the method;

FIG. 16 illustrates another step of the method;

FIG. 17 illustrates a step of an embodiment of a method of manufacturing the display screen of FIG. 6;

FIG. 18 illustrates another step of the method;

FIG. 19 illustrates another step of the method;

FIG. 20 illustrates another step of the method; and

FIG. 21 illustrates another step of the method.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, it is here considered that the terms “insulating” and “conductive” respectively signify “electrically insulating” and “electrically conductive”.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings or to a display screen in a normal position of use.

Unless specified otherwise, the expressions “around”, “approximately”, “substantially” and “in the order of” signify within 10%, and preferably within 5%.

In the following description, the inner transmittance of a layer corresponds to the ratio of the intensity of the radiation coming out of the layer to the intensity of the radiation entering the layer. The absorption of the layer is equal to the difference between number 1 (which corresponds to a perfect transmittance for which the entire incident light is transmitted) and the inner transmittance. In the following description, a layer is said to be transparent to a radiation when the absorption of the radiation through the layer is smaller than 75%. In the following description, a layer is called absorbing or opaque to a radiation when the absorption of the radiation in the layer is greater than 75%. In the following description, a layer is called reflective to a radiation when the reflection of the radiation by the layer is greater than 75%. In the following description, the refraction index of a material corresponds to the refraction index of the material for the wavelength range of the radiation emitted by the light source of the image acquisition system. Unless indicated otherwise, the refraction index is considered as substantially constant over the wavelength range of the radiation emitted by the light source of the image acquisition system, for example, equal to the average of the refraction index over the wavelength range of the radiation emitted by the light source of the image acquisition system.

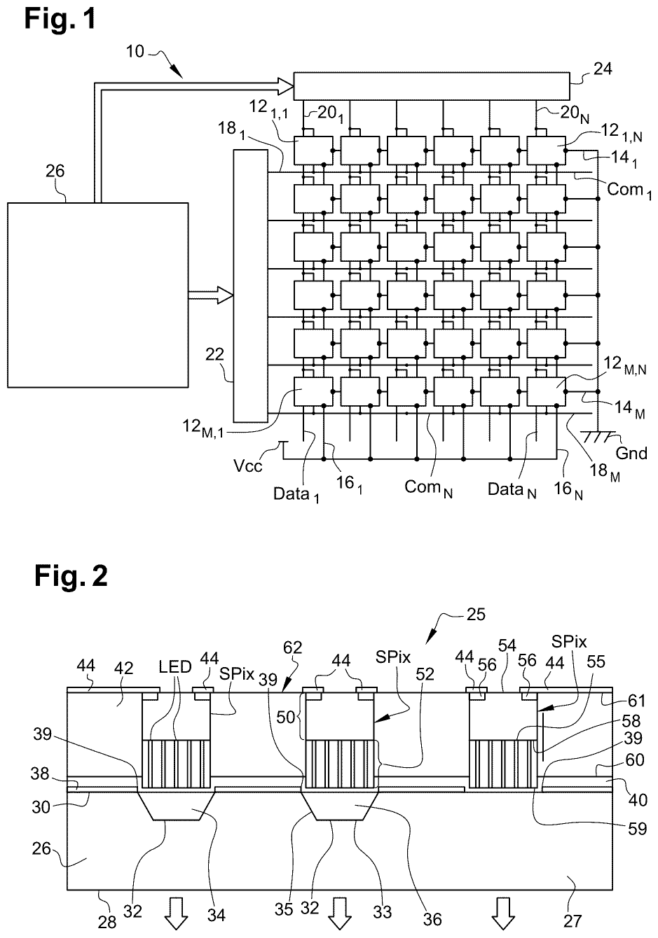

FIG. 1 partially and schematically shows an example of a display screen 10. Display screen 10 comprises display pixels 12_{i,j}, for example, arranged in M rows and in N columns, M being an integer varying from 1 to 8,000 and N being an integer varying from 1 to 16,000, i being an integer varying from 1 to M and j being an integer varying from 1 to N. As an example, in FIG. 1, M and N are equal to 6. Each display pixel 12_{i,j} is coupled to a source of a low reference potential Gnd, for example, the ground, via an electrode 14ᵢ and to a source of a high reference potential Vcc via an electrode 16ⱼ. As an example, electrodes 14ᵢ are shown as being aligned along the rows in FIG. 1 and electrodes 16ⱼ are shown as being aligned along the columns in FIG. 1, the reverse layout being possible. The power supply voltage of the display screen corresponds to the voltage between high reference potential Vcc and low reference potential Gnd.

For each row, the display pixels 12_{i,j} in the row are coupled to a row electrode 18ᵢ. For each column, the display pixels 12_{i,j} in the column are coupled to a column electrode 20ⱼ. Display screen 10 comprises a selection circuit 22 coupled to row electrodes 18ᵢ and adapted to delivering a selection and timing signal Comᵢ on each row electrode 18ᵢ. Display screen 10 comprises a data delivery circuit 24 coupled to column electrodes 20ⱼ and adapted to delivering a data signal Dataⱼ on each column electrode 20ⱼ. Selection circuit 22 and control circuit 24 are controlled by a circuit 23, for example comprising a microprocessor.

According to an embodiment, each display pixel comprises a plurality of display sub-pixels and each display sub-pixel may comprise a control circuit covered with a display circuit. The display circuit may comprise a light-emitting diode or light-emitting diodes. According to another embodiment, the sub-pixels of a same pixel are integrated in a single display circuit associated with a single control circuit. The control circuit may correspond to an integrated circuit configured to control the light-emitting diode or the light-emitting diodes of the display circuit and comprising electronic components, particularly insulated gate field-effect transistors, also called MOS transistors, or thin-film transistors, also called TFT transistors. It is then spoken of smart pixels.

FIG. 2 is a partial simplified cross-section view of an embodiment of a display pixel 25 comprising smart display sub-pixels SPix. Display screen 25 comprises from bottom to top in FIG. 2:
a support 26 comprises two opposite surfaces 28 and 30, surface 28 corresponding to the emission surface of the display screen;
holes 32 in surface 30 at the location of certain display sub-pixels SPix, each hole 32 comprising a bottom 33 and lateral walls 35;
photoluminescent blocks 34, 36 filling holes 32;
an opaque layer 38 covering surface 30 of support 26 and crossed by openings 39 exposing photoluminescent blocks 34, 36 and portions of surface 30 of support 26;
a glue layer 40 covering opaque layer 38 and, in openings 39, photoluminescent blocks 34, 36 or the surface 30 of support 26;
display sub-pixels SPix bonded to support 26 by glue layer 40 in front of openings 39, three display sub-pixels being shown as an example in FIG. 2;
a filling layer 42 covering glue layer 40 between display sub-pixels SPix; and
conductive tracks 44 extending on filling layer 42 and on display sub-pixels SPix.

Each display sub-pixel SPix comprises a control circuit 50 covered with a display circuit 52.

Control circuit 50 comprises two opposite surfaces 54 and 55, preferably parallel. Control circuit 50 is bonded to display circuit 52 by surface 55. Control circuit 50 further comprises conductive pads 56 exposed on surface 54. Control circuit 50 may comprise a semiconductor substrate, not shown, covered with at least one metallization level, not shown. In particular, control circuit 50 may correspond to an integrated circuit comprising electronic components, particularly MOS transistors, or TFT transistors. Control circuit 50 may further comprise conductive through vias, not shown, extending over a portion of the thickness of control circuit 50 and enabling to connect conductive pads 56 to other electronic components of the general control circuit or to connect conductive pads 56 directly to display circuit 52. All the electric connections of display sub-pixel SPix are formed on the side of surface 54.

Display circuit 52 comprises two opposite surfaces 58 and 59, preferably parallel. Surface 59 of display circuit 52 forms the emission surface of display sub-pixel SPix. Surface 58 of display circuit 52 is bonded to surface 55 of control circuit 50. Display circuit 52 comprises at least one light-emitting diode LED, preferably at least three light-emitting diodes LED. The majority, preferably all, of the radiations emitted by the light-emitting diodes LED of the display sub-pixel is emitted by surface 59 of display circuit 52. Preferably, display circuit 52 comprises only light-emitting diodes LED, and the conductive elements of these light-emitting diodes LED and control circuit 50 comprises all the electronic components necessary for the control of the light-emitting diodes LED of display circuit 52. As a variant, display circuit 52 may also comprise other electronic components in addition to light-emitting diodes LED. Light-emitting diodes LED may be 2D light-emitting diodes, also called planar light-emitting diodes, comprising a stack of planar layers, or 3D light-emitting diodes, each comprising a three-dimensional semiconductor element covered with an active area emitting the majority of the radiation of the light-emitting diode.

Each display sub-pixel SPix may have a cylindrical general shape with a cross-section capable of having different shapes, such as, for example an oval, circular, or polygonal, particularly triangular, rectangular, square or hexagonal, shape. The maximum lateral dimension of display sub-pixel SPix in top view may be in the range from 4 μm to 2 mm, preferably from 20 μm to 200 um. The thickness of display sub-pixel SPix, that is, the distance between surfaces 54 and 59, may be in the range from 0.5 μm to 1 mm, preferably from 10 μm to 150 μm. The thickness of control circuit 50 may be in the range from 0.5 μm to 750 μm. The thickness of display circuit 52 may be in the range from 2 μm to 100 μm. The distance in top view of two adjacent display sub-pixels SPix may be in the range from 10 μm to 10 mm.

Support 26 corresponds to the structure having display sub-pixels SPix resting thereon. Support 26 may be all in one piece or have a multilayer structure. In the embodiment shown in FIG. 2, support 26 comprises a base 27 all in one piece. At least a portion of support 26 is transparent to the radiations of the light-emitting diodes LED of display sub-pixels SPix and to the radiations emitted by photoluminescent blocks 34, 36. Preferably, the portion of support 26 which extends from emission surface 28 to the bottoms 33 of holes 32 is transparent to the radiations of the light-emitting diodes LED and of display sub-pixels SPix and to the radiations emitted by photoluminescent blocks 34, 36. In the present embodiment, base 27 is transparent to the radiations of the light-emitting diodes LED of display sub-pixels SPix and to the radiations emitted by photoluminescent blocks 34, 36. Base 27 is for example made of glass or of polymer, for example polyethylene naphthalene (PEN), polyethylene terephthalate (PET), polyimide (PI), and polyetheretherketone (PEEK). The maximum thickness of support 26, that is, the distance between surfaces 28 and 30, may be in the range from 1 μm to 1 cm, preferably from 40 μm to 5 mm.

The maximum depth of each hole 32 may be in the range from 1 μm to 200 μm, preferably from 4 μm to 50 μm. The maximum lateral dimension of each hole 32 in top view may be in the range from 40 μm to 200 μm, preferably from 100 μm to 110 μm. Each hole 32 may have a cross-section at the level of upper surface 30 capable of having different shapes, such as, for example, an oval, circular, or polygonal, particularly triangular, rectangular, square, or hexagonal shape. Each hole 32 may have a cross-section at the level of upper surface 30 having an area greater than the area of the cross-section of a display sub-pixel SPix. Each hole 32 is located in front of one of display sub-pixels SPix. This means that the projection of the cross-section of display sub-pixel SPix on surface 30 along a direction perpendicular to surface 30 is mainly, preferably by more than 75%, more preferably entirely, contained in the cross-section of the associated hole 32 at the level of upper surface 30.

Each photoluminescent block 34, 36 may comprise luminophores capable, when they are excited by the light emitted by the light-emitting diode LED of the display sub-pixel SPix covering photoluminescent block 34, 36, of emitting light at a wavelength different from the wavelength of the light emitted by the associated light-emitting diodes LED. According to an embodiment, display screen 25 comprises at least two types of photoluminescent blocks 34, 36. Each photoluminescent block 34 of the first type is capable of converting the radiation supplied by the light-emitting diodes of the associated display sub-pixel SPix into a first radiation at a first wavelength, and each photoluminescent block 36 of the second type is capable of converting the radiation supplied by the light-emitting diodes of the associated display sub-pixel SPix into a second radiation at a second wavelength. According to an embodiment, display screen 25 comprises at least three types of photoluminescent blocks, each photoluminescent block of the third type being adapted to converting the radiation supplied by the light-emitting diodes of the associated display sub-pixel SPix into a third radiation at a third wavelength. The first, second, and third wavelengths may be different.

According to an embodiment, the light-emitting diodes LED are all adapted to emitting blue light, that is, a radiation having its wavelength in the range from 430 nm to 480 nm. According to an embodiment, the first wavelength corresponds to green light and is in the range from 510 nm to 570 nm. According to an embodiment, the second wavelength corresponds to red light and is in the range from 600 nm to 720 nm.

According to another embodiment, the light-emitting diodes LED are all adapted to emitting a radiation in the ultraviolet range, typically having a wavelength below 400 nm. According to an embodiment, the first wavelength corresponds to blue light and is within the range from 430 nm to 480 nm. According to an embodiment, the second wavelength corresponds to green light and is within the range from 510 nm to 570 nm. According to an embodiment, the third wavelength corresponds to red light and is within the range from 600 nm to 720 nm.

According to an embodiment, each photoluminescent block 34, 36 comprises a matrix having nanometer-range monocrystalline particles of a semiconductor material, also called semiconductor nanocrystals or nano-luminophore particles hereafter, dispersed therein. The internal quantum efficiency QYᵢₙₜ of a photoluminescent material is equal to the ratio of the number of emitted photons to the number of photons absorbed by the photoluminescent substance. The internal quantum efficiency QYᵢₙₜ of semiconductor nanocrystals is greater than 5%, preferably greater than 10%, more preferably greater than 20%.

According to an embodiment, the average size of the nanocrystals is in the range from 0.5 nm to 1,000 nm, preferably from 0.5 nm to 500 nm, more preferably from 1 nm to 100 nm, particularly from 2 nm to 30 nm. For dimensions smaller than 50 nm, the photoconversion properties of semiconductor nanocrystals essentially depend on quantum confinement phenomena. The semiconductor nanocrystals then correspond to quantum dots.

According to an embodiment, the semiconductor material of the semiconductor crystals is selected from the group comprising cadmium selenide (CdSe), indium phosphide (InP), cadmium sulfide (CdS), zinc sulfide (ZnS), zinc selenide (ZnSe), cadmium telluride (CdTe), zinc telluride (ZnTe), cadmium oxide (CdO), zinc cadmium oxide (ZnCdO), cadmium zinc sulfide (CdZnS), cadmium zinc selenide (CdZnSe), silver indium sulfide (AgInS₂), perovskites of PbScX₃ type where X is a halogen atom, particularly iodine (I), bromine (Br), or chlorine (Cl), and a mixture of at least two of these compounds. According to an embodiment, the semiconductor material of the semiconductor nanocrystals is selected from the materials mentioned in Le Blevenec et al.'s publication in Physica Status Solidi (RRL)—Rapid Research Letters Volume 8, No. 4, pages 349-352, April 2014.

According to an embodiment, the dimensions of the semiconductor nanocrystals are selected according to the desired wavelength of the radiation emitted by the semiconductor nanocrystals. As an example, CdSe nanocrystals having an average size in the order of 3.6 nm are capable of converting blue light into red light and CdSe nanocrystals having an average size in the order of 1.3 nm are capable of converting blue light into green light. According to another embodiment, the composition of the semiconductor nanocrystals is selected according to the desired wavelength of the radiation emitted by the semiconductor nanocrystals.

The matrix is at least partly transparent to the radiation emitted by the photoluminescent particles and/or light-emitting diodes LED, preferably by more than 80%. The matrix is for example made of silica. The matrix is for example made of any at least partly transparent polymer, particularly of silicone, of acrylic resin of poly(methyl methacrylate) (PMMA) type or of polylactic acid (PLA). The matrix may in particular be made of an at least partly transparent polymer used with three-dimensional printers. The matrix may correspond to photosensitive or non-photosensitive glass deposited by centrifugation (SOG, Spin-On Glass). According to an embodiment, the matrix contains from 2% to 90%, preferably from 10 wt. % to 60 wt. %, of nanocrystals, for example, approximately 30 wt. % of nanocrystals. The thickness of photoluminescent blocks 34, 36, which is equal to the depth of holes 32, depends on the nanocrystal concentration and the type of nanocrystals used.

Opaque layer 38 is opaque to the radiation emitted by light-emitting diodes LED. Opaque layer 38 is preferably black-colored. Opaque layer 38 may be made of resin. The thickness of opaque layer 38 may be in the range from 1 μm to 10 μm.

Glue layer 40 is transparent to the radiation emitted by light-emitting diodes LED. Layer 40 may be an optically clear adhesive (OCA), particularly a liquid optically clear adhesive (LOCA). Preferably, the refraction index of glue layer 40 is smaller than 2. The maximum thickness of glue layer 40 may be in the range from 10 nm to 5 μm. According to an embodiment, glue layer 40 is electrically insulating. Each display sub-pixel SPix comprises no electric connections on the side of glue layer 40.

Filling layer 42 surrounds each display sub-pixel SPix. Filling layer 42 comprises two opposite surfaces 60 and 61, preferably planar and parallel. Surface 60 is in mechanical contact with glue layer 40. The surface 61 of filling layer 42 forms, with the surface 54 of each display sub-pixel SPix, a rear surface 62 of display screen 25. Preferably, the surface 61 of filling layer 42 and the surfaces 54 of display sub-pixels SPix are planar and coplanar, so that rear surface 62 is planar. Filling layer 42 is preferably made of an insulating material. Filling layer 42 is reflective to the radiation emitted by light-emitting diodes LED. Filling layer 42 is preferably white-colored. As an example, filling layer 42 is made of PMMA-type acrylic resin filled with particles, particularly titanium oxide (TiO₂) particles. The thickness of filling layer 42 may be substantially equal to the thickness of display sub-pixel SPix decreased by the maximum thickness of glue layer 40.

Conductive tracks 44 extend on the surfaces 55 of some of display sub-pixels SPix and on the surface 61 of filling layer 42. Conductive tracks 44 are for example made of copper (Cu). The thickness of each conductive track 44 may be in the range from 200 nm to 100 μm.

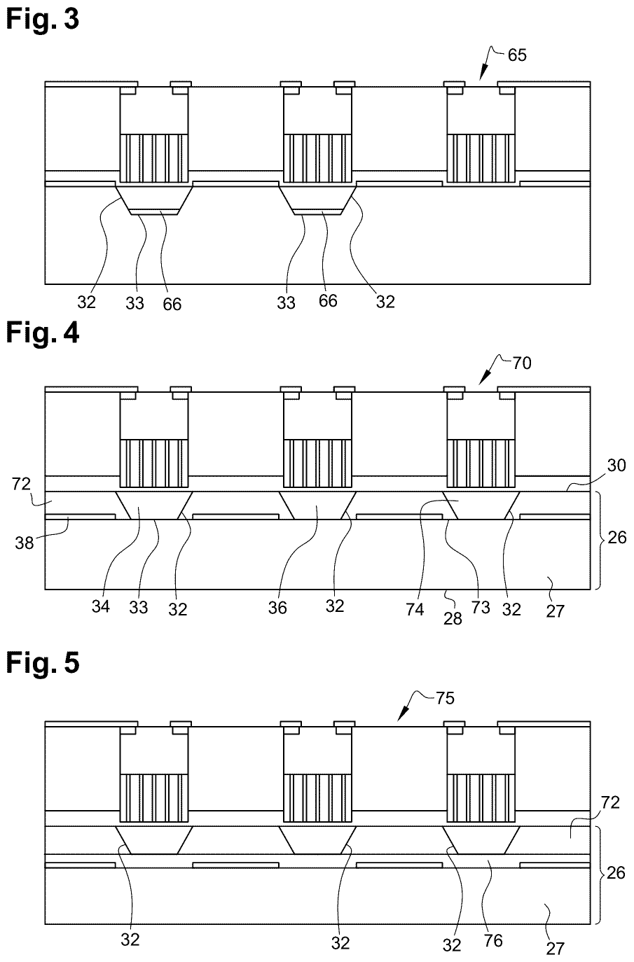

FIG. 3 is a partial simplified cross-section view of an embodiment of a display screen 65. Display screen 65 comprises all the elements of the display screen 25 shown in FIG. 2 and further comprises a layer 66 corresponding to a color filter covering at least the bottom 33 of at least some of holes 32. Layer 66 enables to more finely adapt the spectrum of the radiation emitted towards the emission surface 28 of display screen 65. In particular, layer 66 enables to block the residual blue radiation. Layer 66 for example corresponds to a yellow color filter.

FIG. 4 is a partial simplified cross-section view of an embodiment of a display screen 70. Display screen 70 comprises all the elements of the display screen 65 shown in FIG. 3 with the difference that support 26 comprises a layer 72 covering base 27 and that holes 32 are formed in layer 72. Further, a hole 32 is present in front of each display sub-pixel SPix. Layer 72 delimits the surface 30 of support 26 and comprises a lower surface 73, opposite to surface 30 and in mechanical contact with base 27. Layer 72 is preferably reflective to the radiations emitted by light-emitting diodes LED. Layer 72 is preferably white-colored. The thickness of layer 72 is substantially equal to the maximum depth of holes 32, so that holes 32 fully cross layer 72 and that the bottom 33 of holes 32 corresponds to a portion of base 27. Layer 72 may be made of a resist. In the present embodiment, opaque layer 38 rests on base 27, in mechanical contact with base 27. As a variant, opaque layer 38 may rest on layer 72. Holes 32 are filled with photoluminescent blocks 34, 36 or with a block 74 of a scattering material. The scattering character of the material may be characterized by the bidirectional scattering distribution function (BSDF), particularly comprising the bidirectional reflectance distribution function (BRDF) and the bidirectional transmittance distribution function (BTDF). The bidirectional scattering distribution function may be determined by a dedicated measurement tool. According to an embodiment, the scattering material of block 74 comprises a matrix having reflective particles dispersed therein. The matrix may be made of a material transparent to the radiations emitted by light-emitting diodes LED. The matrix may comprise silicon oxide (SiO₂), a silicone polymer, an epoxide polymer, an acrylic polymer, or a polycarbonate. The particles are for example titanium oxide particles (TiO₂).

FIG. 5 is a partial simplified cross-section view of an embodiment of a display screen 75. Display screen 75 comprises all the elements of the display screen 70 shown in FIG. 4 with the difference that support 26 comprises an additional layer 76 interposed between base 27 and layer 72 containing holes 32. Layer 76 is a glue layer which allows the bonding of layer 72 containing holes 32 onto base 27. Layer 76 is transparent to the radiations of the light-emitting diodes LED of display sub-pixels SPix and to the radiations emitted by photoluminescent blocks 34, 36. Layer 76 may be made of an optically clear adhesive (OCA), particularly a liquid optically clear adhesive (LOCA). Preferably, the refraction index of layer 76 is smaller than 2. The thickness of layer 76 may be in the range from 10 nm to 10 μm.

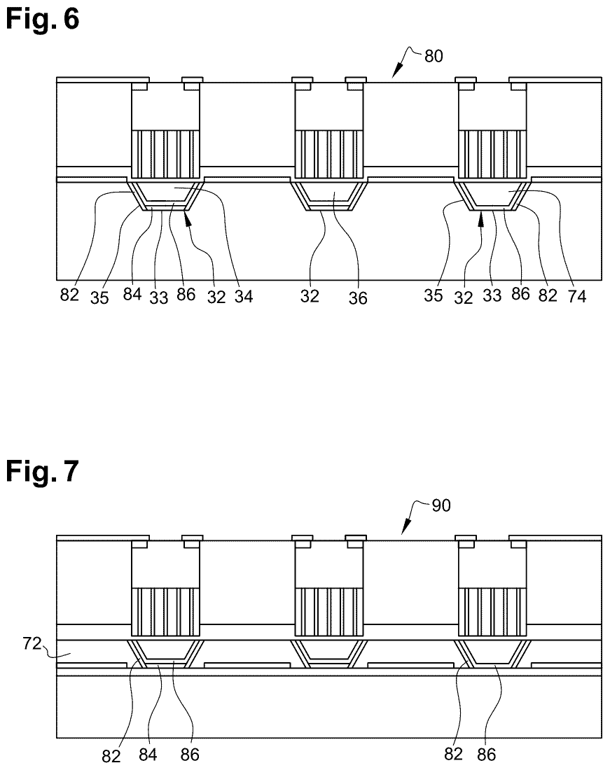

FIG. 6 is a partial simplified cross-section view of an embodiment of a display screen 80. Display screen 80 comprises all the elements of the display screen 25 shown in FIG. 2, with the difference that a hole 32 is present in front of each display sub-pixel SPix, that it further comprises a reflective coating 82 covering the lateral walls 35 of holes 32, that it comprises a color filter 84 covering the bottom 33 of first holes 32, that it comprises, on the lateral walls 35 and the bottom 33 of first holes 32, a layer 86 transparent to the radiations of photoluminescent blocks 34, 36, and that it comprises, on the lateral walls 35 and the bottom 33 of second holes 32, transparent layer 86 only. Transparent layer 86 enables to increase the conversion efficiency of photoluminescent blocks 34 and 36. As a variant, transparent layer 86 may only be present on the bottom 33 of the first holes 32 and/or of the second holes 32. Layer 34 for example corresponds to a yellow color filter. The first holes 32 are filled with photoluminescent blocks 34, 36 and the second holes 32 with the blocks 74 of the scattering material as previously described for display screen 70. Reflective coating 82 may be a metal layer, for example, an aluminum or silver layer, or comprise a stack of dielectric layers forming a Bragg mirror. The thickness of reflective coating 82 may be in the range from 50 nm to 1.5 μm. The thickness of layer 84 may be in the range from 250 nm to 3 μm. Preferably, the refraction index of layer 86 is smaller than 1.5. Transparent layer 86 may be made of polymer. The thickness of layer 86 may be in the range from 250 nm to 2 μm.

FIG. 7 is a partial simplified cross-section view of an embodiment of a display screen 90. Display screen 90 comprises all the elements of the display screen 75 shown in FIG. 5, and further comprises the reflective coatings 82, the colored filter layers 84, and the transparent layers 86 previously described for display screen 80.

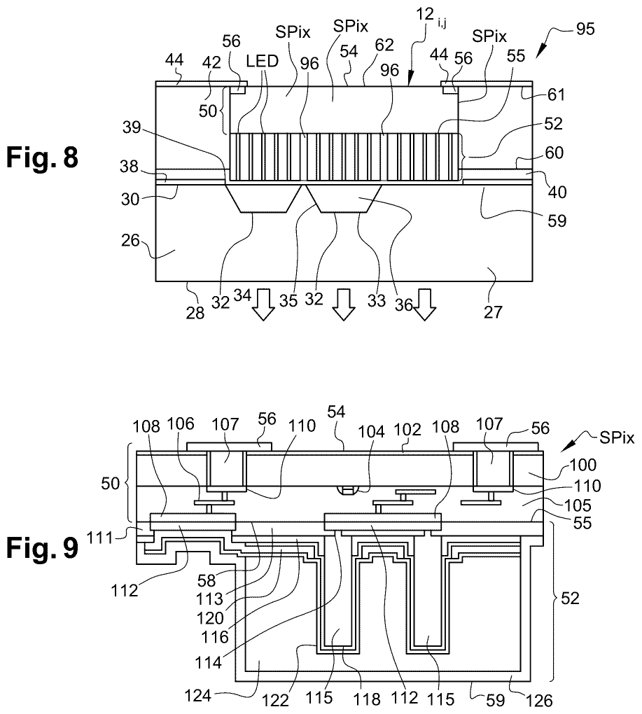

FIG. 8 is a partial simplified cross-section view of an embodiment of a display screen 95. Display screen 95 comprises all the elements of the display screen 25 shown in FIG. 2 with the difference that, for at least certain display pixels, the sub-pixels SPix of the display pixel are integrated in a single display circuit 52 associated with a single control circuit 50. According to an embodiment, display circuit 52 comprises separation elements 96 separating the light-emitting diodes LED of display sub-pixels SPix. Separation elements 96 do not let through the radiation emitted by light-emitting diodes LED. These separation elements 96 thus enable to avoid for the light emitted by the light-emitting diodes LED of a display sub-pixel SPix to reach the photoluminescent block 32, 34 of another display sub- pixel SPix, or the opening in front of display sub-pixel SPix to which no photoluminescent block is associated, which would modify the spectrum and the emission intensity of display sub-pixel SPix, and would adversely affect the sharpness of the displayed image.

FIG. 9 is a partial simplified cross-section view of a more detailed embodiment of a display sub-pixel SPix.

According to an embodiment control circuit 50 comprises from top to bottom in FIG. 9:
a semiconductor substrate 100, for example, single-crystal silicon, an insulating layer 102 delimiting surface 54 and the conductive pads 56 exposed on lower surface 54;
MOS transistors 104, formed inside and on top of substrate 100;
a stack 105 of insulating layers, for example, made of silicon oxide and/or of silicon nitride, covering substrate 100 and the conductive tracks 106 of a plurality of metallization levels formed between the insulating layers of stack 105, having in particular pads 108 exposed on the surface 55 of control circuit 50, where the conductive tracks 106 of the first metallization level may be made of polysilicon and particularly form the gates of MOS transistors 104 and where the conductive tracks 106 of the other metallization levels may be metal tracks, for example, made of aluminum, of silver, of copper, or of zinc; and
conductive and laterally-insulated vias 107, also called TSVs (Through Silicon Vias) crossing substrate 100 and coupling pads 56 to pads 110 of the first metallization level of stack 105.

According to an embodiment, display circuit 52 comprises from top to bottom in FIG. 9:
a support 111 forming the surface 58 of display circuit 52 in contact with the surface 55 of control circuit 50 and comprising conductive pads 112 exposed on surface 58, in contact with pads 110, and a multilayer insulating structure 113, for example, made of silicon oxide and of silicon nitride, extending between pads 112 and covering pads 112 and comprising openings 114 exposing portions of pads 112;
microwires or nanowires 115, called wires hereafter (two wires being shown), each wire 115 being in contact with one of pads 112 through one of opening 114;
an insulating layer 116 extending on the lateral sides of a lower portion of each wire 115 and extending on insulating layer 113 between wires 115;
a shell 118 comprising a stack of semiconductor layers covering an upper portion of each wire 115 and extending on insulating layer 116 between wires 115, shell 118 particularly comprising an active layer which is the layer from which most of the radiation supplied by the light-emitting diode is emitted and comprising, for example, confinement means, such as multiple quantum wells;
a conductive and reflective layer 120, extending on shell 118 between wires 115;
a transparent conductive layer 122 forming an electrode covering, for each wire 115, shell 118 and further extending on conductive layer 120 between wires 115;
a transparent or scattering block 124 covering light-emitting diodes LED; and
an encapsulation layer 126 covering the entire structure.

Each wire 115 may have an elongated semiconductor structure. Each wire 115 may have a cylindrical general shape with a cross-section capable of having different shapes, such as, for example an oval, circular, or polygonal, particularly triangular, rectangular, square or hexagonal, shape. Each wire 115 for example has a mean diameter, for example corresponding to the diameter of the disk having the same area as the cross-section of wire 115, in the range from 5 nm to 5
m, preferably from 100 nm to 2
m, more preferably from 200 nm to 1.5
m, and a height greater than or equal to 1 time, preferably greater than or equal to 3 times and more preferably still greater than or equal to 5 times the mean diameter, particularly greater than 500 nm, preferably in the range from 1
m to 50
m. Wires 115 comprise at least one semiconductor material. The semiconductor material may be silicon carbide, a III-V compound, for example, GaN, AlN, InN, InGaN, AlGaN, or AlInGaN, a II-VI compound, or a combination of at least two of these compounds.

Conductive layer 122 is capable of biasing the active layers of shells 118 and of letting through the electromagnetic radiation emitted by the light-emitting diodes. The material forming conductive layer 122 may be a transparent conductive material such as graphene or a transparent conductive oxide (TCO), particularly indium tin oxide (ITO), zinc oxide, doped or not with aluminum, or with gallium, or with boron, or silver nanowires. As an example, conductive layer 122 has a thickness in the range from 20 nm to 500 nm, preferably from 20 nm to 100 nm.

Conductive layer 120, conductive tracks 106, and conductive pads 56, 108, 112 may be made of metal, for example, of aluminum, silver, platinum, nickel, copper, gold, or ruthenium, or of an alloy comprising at least two of these compounds, particularly the PdAgNiAu alloy or the PtAgNiAu alloy. Conductive layer 120 may have a thickness in the range from 100 nm to 3
m. Conductive pads 56, 108, 112 may have a thickness in the range from 0.5
m to 2
m.

Each of insulating layers 105, 111, 116 is made of a material selected from the group comprising silicon oxide (SiO₂), silicon nitride (SiₓN_{y}, where x is approximately equal to 3 and y is approximately equal to 4, for example, Si₃N₄), silicon oxynitride (particularly of general formula SiOₓN_{y}, for example, Si₂ON₂), hafnium oxide (HfO₂), titanium oxide (TiO₂), or aluminum oxide (Al₂O₃).

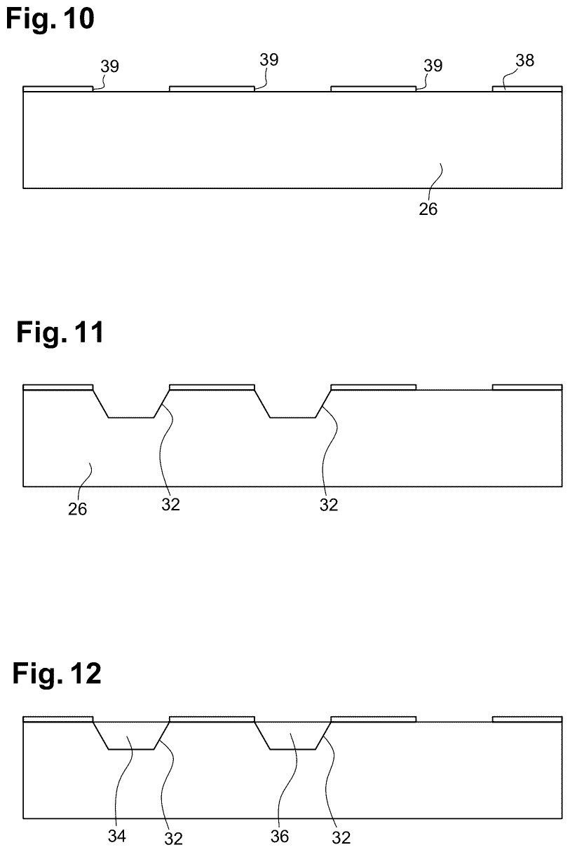

FIGS. 10 to 16 are partial simplified cross-section views of structures obtained at successive steps of an implementation mode of the display screen 25 shown in FIG. 2.

FIG. 10 shows the structure obtained after a step of forming, on surface 30, of the support 26 of opaque layer 38. This step may comprise the deposition over the entire surface 30 of the material forming layer 38 and the etching of this material to form openings 39 at the anticipated locations of the display sub-pixels.

FIG. 11 shows the structure obtained after a step of forming of holes 32 in support 26. Holes 32 may be formed by etching, particularly a reactive ion etching (RIE).

FIG. 12 shows the structure obtained after a step of forming of photoluminescent blocks 34, 36 in holes 32. According to the considered materials, the method of forming blocks 32 and 36 may correspond to a method called additive, for example, by direct printing of the material forming blocks 32 and 36 at the desired locations, for example by inkjet printing, heliography, silk-screening, flexography, spray coating, or drop casting. According to the considered material, the method of forming blocks 32, 36 may correspond to a so-called subtractive process, where the material forming blocks 32 and 36 is deposited over the entire structure and where the non-used portions are then removed, for example, by photolithography or laser ablation. Methods such as spin coating, spray coating, heliography, slot-die coating, blade coating, flexography, or silk-screening, may in particular be used.

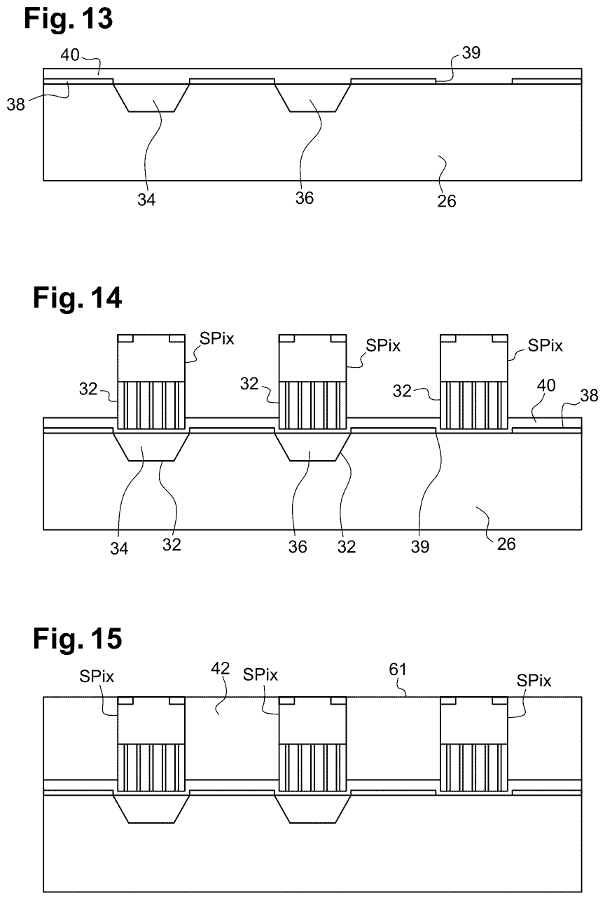

FIG. 13 shows the structure obtained after a step of deposition of glue layer 40 on a surface of the structure shown in FIG. 12, in particular on opaque layer 38, photoluminescent blocks 34, 36, and the exposed portions of support 26 in the openings 39 of opaque layer 38. At this step, glue layer 40 may be in liquid form, more or less viscous. The deposition of glue layer 40 may be performed by one of the methods previously described for the forming of photoluminescent blocks 34 and 36.

FIG. 14 shows the structure obtained after a step of arranging of display sub-pixels SPix on support 26, each display sub-pixel SPix being placed in front of a hole 32 or in front of an exposed portion of support 26 in an opening 39 of opaque layer 38. According to an embodiment, this step comprises the sinking of each display sub-pixel SPix into glue layer 40 on the side of display circuits 32 and a glue solidification step, capable of comprising a heating step and/or a step of exposure to an ultraviolet or infrared radiation. A film of glue layer 40 may persist between display sub-pixel SPix and support 26 or photoluminescent blocks 34, 36 after the arranging of display sub-pixel SPix. Glue layer 40 is then transparent to the radiation emitted by light-emitting diodes LED. The refraction index of glue layer 40, preferably smaller than 2, is adapted to the extraction and the propagation of the radiation emitted by the light-emitting diodes. A method of manufacturing the display sub-pixels comprises the forming of a plurality of display circuits on a wafer, called optoelectronic wafer, the forming of a plurality of control circuits on a wafer, called logic wafer, the bonding of the optoelectronic wafer to the logic wafer, and the cutting of the stack of the optoelectronic wafer and of the logic wafer to separate the display pixels.

FIG. 15 shows the structure obtained after a step of forming of filling layer 42. The deposition of filling layer 42 may be performed by one of the methods previously described for the forming of photoluminescent blocks 34 and 36. A planarization step may be provided to form surface 61.

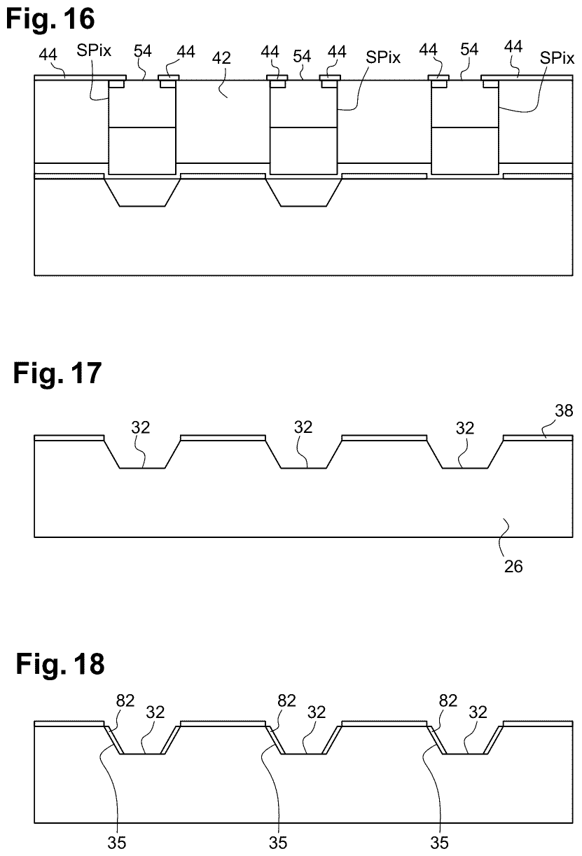

FIG. 16 shows the structure obtained after a step of forming of conductive tracks 44. The material forming the conductive tracks is, for example, deposited by evaporation or by cathode sputtering over the entire filling layer 42 and the surfaces 54 of display sub-pixels SPix and conductive tracks 44 are delimited by etching.

In the previously-described embodiments, each display pixel/display sub-pixel comprises control circuit 50 which integrates the control electronics of the light-emitting diodes LED of the display pixel/display sub-pixel. This particularly enables to be able to directly form conductive tracks 44 on surface 61, after a possible planarization step, and thus allows, before the forming of conductive tracks 44, the direct transfer of the display sub-pixels onto support 26 comprising photoluminescent blocks 34, 36, conversely to a conventional method where the display pixels/display sub-pixels are deposited on a slab comprising the control electronics and the photoluminescent blocks are then formed on the display pixels/display sub-pixels. If each pixels/display sub-pixel did not comprise control circuit 50, it would be difficult, or even it would not be possible, to deposit the pixels/display sub-pixels on support 26 comprising photoluminescent blocks 34, 36. Indeed, electronic components would then have to be formed or deposited on a structure having already been transferred, which may not be compatible with accuracy constraints for the forming/the deposition of electronic components.

An embodiment of a method of manufacturing the display screen 65 shown in FIG. 3 comprises all the steps previously described in relation with FIGS. 10 to 12 and further comprises, before the step of forming of photoluminescent blocks 34 and 36 previously described in relation with FIG. 12, a step of forming of color filter layers 66 in holes 32.

An embodiment of a method of manufacturing the display screen 70 shown in FIG. 4 comprises all the steps previously described in relation with FIGS. 10 to 16, with the difference that it further comprises a step of forming of layer 72 on base 27 before the step of forming of holes 32, and that holes 32 are formed in layer 72, for example, by etching of layer 72. Advantageously, the material forming layer 72 may be selected so that a step of etching in layer 72 is simpler to implement than a step of etching in base 27.

An embodiment of a method of manufacturing the display screen 75 shown in FIG. 5 comprises all the steps previously described for the manufacturing of display screen 70 and further comprises a step of forming of layer 76 before the step of forming of layer 72.

FIGS. 17 to 21 are partial simplified cross-section views of structures obtained at successive steps of an embodiment of the display screen 80 shown in FIG. 6.

FIG. 17 shows the structure obtained after a step of forming on support 26 of opaque layer 38 and the forming of holes 32, for example, as described previously in relation with FIGS. 10 and 11.

FIG. 18 shows the structure obtained after a step of forming of reflective coatings 82 on the lateral walls 35 of holes 32. The material forming reflective coating 82 is for example deposited by evaporation or by cathode sputtering over the entire support 26 and reflective coatings 82 are delimited by etching.

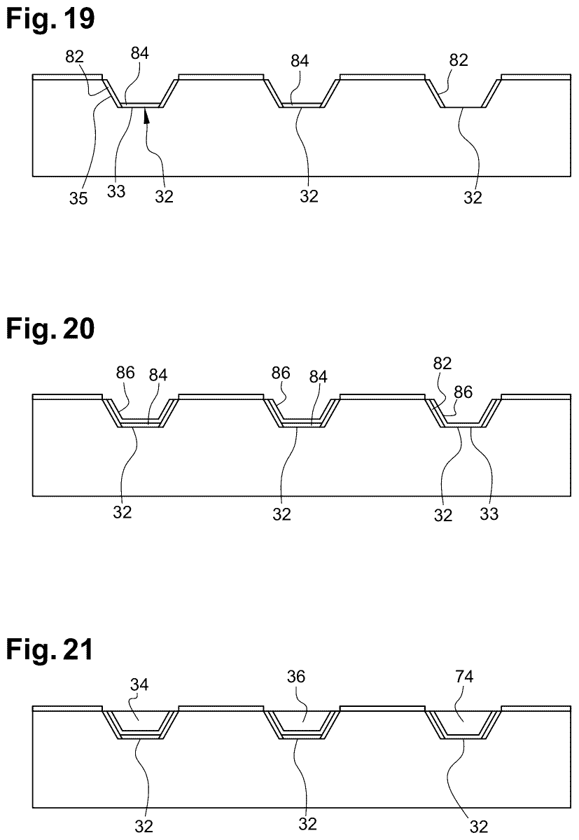

FIG. 19 shows the structure obtained after a step of forming of color filter layer 84 in each hole 32 intended to receive a photoluminescent block 34 or 36, covering the bottom 33 of the hole.

FIG. 20 shows the structure obtained after a step of forming, in each hole 32, of transparent layer 86 covering color filter layer 84 and the reflective coating 82 in each hole 32 intended to receive a photoluminescent block 34 or 36 or directly covering reflective coating 82 and the bottom 33 of hole 32 in each hole 32 intended to receive a scattering block 74.

FIG. 21 shows the structure obtained after a step of forming of photoluminescent blocks 34, 36 and of scattering blocks 74 in holes 32, for example, as previously described in relation with FIG. 12.

The method of manufacturing the screen 80 shown in FIG. 6 may comprise the steps previously described in relation with FIGS. 13 to 16.

Various embodiments and variants have been described. Those skilled in the art will understand that certain features of these various embodiments and variants may be combined, and other variants will occur to those skilled in the art. Further, although in the previously-described embodiments display sub-pixel SPix comprises two chips bonded to each other, it should be clear that the group of pixels may comprise a single chip, the general circuit for controlling the light-emitting diodes being formed so as to be integrated with the light-emitting diodes. Finally, the practical implementation of the described embodiments and variations is within the abilities of those skilled in the art based on the functional indications given hereabove.

1. Display screen comprising:
a support comprising first and second opposite surfaces and holes on the first surface;
photoluminescent blocks in at least part of the holes;
a glue layer covering the first surface;
display sub-pixels bonded to the support by the glue layer, each display sub-pixel comprising third and fourth opposite surfaces, the third surface being on the side of the support, and electrically-conductive pads exposed on the fourth surface;
a filling layer covering the first surface between the display sub-pixels; and
electrically-conductive tracks extending on the filling layer and on the fourth surfaces of the display sub-pixels in electrical and mechanical contact with the electrically-conductive pads.

2. Display screen according to claim 1, wherein each display sub-pixel comprises light-emitting diodes closer to the third surface than to the fourth surface.

3. Display screen according to claim 2, wherein each display sub-pixel comprises a stack of a first electronic circuit comprising the light-emitting diodes (LED) and of a second electronic circuit comprising electronic components configured to control the light-emitting diodes.

4. Display screen according to claim 1, wherein the filling layer is reflective for the radiations emitted by the display sub-pixels and the photoluminescent blocks.

5. Display screen according to claim 1, further comprising a first layer opaque to the radiations emitted by the display sub-pixels and the photoluminescent blocks opposite to the first surface and comprising openings in front of the third surface of each display sub-pixel.

6. Display screen according to claim 1, comprising blocks of a material scattering the radiation emitted by the display sub-pixels in at least another portion of the holes.

7. Display screen according to claim 1, wherein the support comprises a base transparent to the radiations emitted by the display sub-pixels and the photoluminescent blocks covered with a second layer containing the holes.

8. Display screen according to claim 7, wherein the second layer is reflective for the radiations emitted by the display sub-pixels and the photoluminescent blocks.

9. Display screen according to claim 7, further comprising, between the base and the second layer, a third layer transparent to the radiations emitted by the display sub-pixels and the photoluminescent blocks and having a refraction index smaller than 2.

10. Display screen according to claim 1, comprising a coating, reflective for the radiations emitted by the display sub-pixels and the photoluminescent blocks, covering the lateral wall of each hole.

11. Display screen according to claim 1, comprising a fourth layer, transparent to the radiations emitted by the display sub-pixels and the photoluminescent blocks , and having a refraction index smaller than 1.5, covering the bottom of each hole.

12. Display screen according to claim 1, comprising, for the holes containing the photoluminescent blocks, a color filter layer interposed between the photoluminescent blocks and the bottoms of the holes.

13. Display screen according to claim 1, wherein the photoluminescent blocks contain quantum dots.

14. Method of manufacturing a display screen according to claim 1, comprising the following steps:
forming the holes on the first surface of the support;
forming of the photoluminescent blocks in at least part of the holes;
deposition of a glue layer covering the first surface;
arranging and bonding of the display sub-pixels bonded to the support by the glue layer, on the side of the third surfaces;
forming of the filling layer covering the first surface between the display sub-pixels; and
forming of the electrically-conductive tracks extending on the filling layer and on the fourth surfaces of the display sub-pixels.

15. Method of manufacturing a display screen according to claim 14, comprising the following steps:
forming of a wafer comprising a plurality of said display sub-pixels; and
cutting of the wafer to separate said display sub-pixels.
